(19) United States
(12) Patent Application Publication
(10) Pub. No.: US 2014/0095088 A1
(43) Pub. Date: Apr. 3, 2014

(54) SYSTEMS AND METHODS FOR CHARACTERIZATION OF ENERGY STORAGE DEVICES

(71) Applicant: CATERPILLAR INC., Peoria, IL (US)

(72) Inventors: Wellington Ying-Wei KWOK, Dunlap, IL (US); Igor Dos Santos RAMOS, Minnetonka, MN (US); Andrew Alfred KNITT, Deer Creek, IL (US); Justin Dale MIDDLETON, Peoria, IL (US)

(73) Assignee: CATERPILLAR INC., Peoria, IL (US)

(21) Appl. No.: 13/630,277

(22) Filed: Sep. 28, 2012

(51) Int. Cl. G01R 31/36; G06F 19/00

(52) U.S. Cl. 702/60

(57) ABSTRACT

A method for characterization of an energy storage device is disclosed. The method includes determining an instantaneous state of charge (SOC) value of the energy storage device during operation the energy storage device, and retrieving an instantaneous available discharging energy value of the energy storage device from a map based on a discharging power and the determined instantaneous SOC value of the energy storage device. The method further includes retrieving an instantaneous acceptable charging energy value of the energy storage device from another map based on a charging power and the determined instantaneous SOC value of the energy storage device.

### TECHNICAL FIELD

The present disclosure relates generally to systems and methods for characterization of energy storage devices and, more specifically, to systems and methods for characterization of energy storage devices during operation of the energy storage devices.

### BACKGROUND

In electric or hybrid machines, typical energy sources and sinks may include various types of energy storage systems such as battery cells, ultra-capacitors, etc. The electric or hybrid machine may include an Energy Management System (EMS) responsible for managing energy flows between these energy sources and sinks. The electric or hybrid machine may also include a Battery Management System (BMS) or a Ultra-Capacitor Management System (UCMS) as a subsystem of the EMS. The BMS or UCMS may manage energy flows into and out of the energy storage systems included in the machine and may provide continual health monitoring and safety protection of those systems. In order to do so, however, it may be important to characterize one or more aspects of the energy storage systems, e.g., available discharging energy, acceptable charging energy, and discharge/charge energy efficiency, during operation of the electric or hybrid machine.

An exemplary system that may be used to estimate power capability of battery packs is disclosed in U.S. Pat. No. 7,969,120 to Plett, that was issued on Jun. 28, 2011 (“the '120 patent”). The system in the '120 patent calculates an available power as a function of state of charge (SOC) and static limits on maximum current and power by using a Taylor series expansion method. In another embodiment, the system calculates the available power dynamically by using a comprehensive cell model method.

Although the system of the '120 patent may be useful in estimating power capability of battery packs, the system of the '120 patent may require complex computation processes, which may consume system resources. In addition, the system of the '120 patent may not be able to estimate the available discharging energy or acceptable charging energy of the battery packs.

The system of the present disclosure is directed toward solving the problem set forth above and/or other problems of the prior art.

### SUMMARY

In one aspect, the present disclosure is directed to a computer-implemented method for characterization of an energy storage device. The method may include determining an instantaneous state-of charge (SOC) value of the energy storage device during operation of the energy storage device, and retrieving an instantaneous available discharging energy value of the energy storage device from a first map based on a discharging power and the determined instantaneous SOC value of the energy storage device. The first map may correlate each of a plurality of available discharging energy values of the energy storage device to a combination of one of a plurality of discharging powers of the energy storage device and one of a plurality of SOC values of the energy storage device.

In another aspect, the present disclosure is directed to a system for characterization of an energy storage device. The system may include a storage device storing a first map correlating each of a plurality of available discharging energy values of the energy storage device to a combination of one of a plurality of discharging powers of the energy storage device and one of a plurality of state-of-charge (SOC) values of the energy storage device. The system may also include one or more memories storing instructions, and one or more processors capable of executing the instructions to determine an instantaneous SOC value of the energy storage device during operation of the energy storage device, and retrieve an instantaneous available discharging energy value of the energy storage device from the first map based on a discharging power and the determined instantaneous SOC value of the energy storage device.

In a further aspect, the present disclosure is directed to a computer-implemented method for characterization of an energy storage device. The method may include determining an instantaneous state of charge (SOC) value of the energy storage device during operation of the energy storage device, and retrieving an instantaneous acceptable charging energy value of the energy storage device from a map based on a charging power and the determined instantaneous SOC value of the energy storage device. The map correlates each of a plurality of acceptable charging energy values of the energy storage device to a combination of one of a plurality of charging powers of the energy storage device and one of a plurality of SOC values of the energy storage device.

### BRIEF DESCRIPTION OF THE DRAWINGS

FIG. 1 is a schematic drawing of an exemplary hybrid electric drivetrain system.

FIG. 2 is a diagrammatic illustration of exemplary operating ranges of an energy storage device.

FIG. 3 is a graphical illustration of exemplary voltage and current profiles of an energy storage device during a constant-power discharge period.

FIG. 4 is a graphical illustration of an exemplary correlation between available discharging energy and discharging power at different instantaneous operating points, that may be obtained according to embodiments of the present disclosure.

FIG. 5 is a graphical illustration of an exemplary revised correlation between available discharging energy and discharging power at different instantaneous operating points with a maximum current limit, that may be obtained according to embodiments of the present disclosure.

FIG. 6 is a graphical illustration of exemplary voltage and current profiles of an energy storage device during a constant-power charge period.

FIG. 7 is a graphical illustration of an exemplary correlation between available discharging energy and discharging power, and between acceptable charging energy and charging power, at different instantaneous operating points, that may be obtained according to embodiments of the present disclosure.

FIG. 8 is a graphical illustration of an exemplary open circuit voltage versus SOC curve of energy storage device 20, that may be obtained according to embodiments of the present disclosure.

FIG. 9 is a graphical illustration of an exemplary correlation between round-trip efficiency and charging and discharging powers of an energy storage device, that may be obtained according to embodiments of the present disclosure.

FIG. 10 is a flowchart depicting an exemplary method for characterizing an energy storage device.

FIG. 11 is a flowchart depicting an exemplary method for establishing a first map.

FIG. 12 is a flowchart depicting an exemplary method for establishing a second map.

FIG. 13 is a flowchart depicting an exemplary method for establishing a third map.

FIG. 14 is a flowchart depicting an exemplary method for establishing a fourth map.

FIG. 15 is a flowchart depicting an exemplary method for establishing a fifth map.

### DETAILED DESCRIPTION

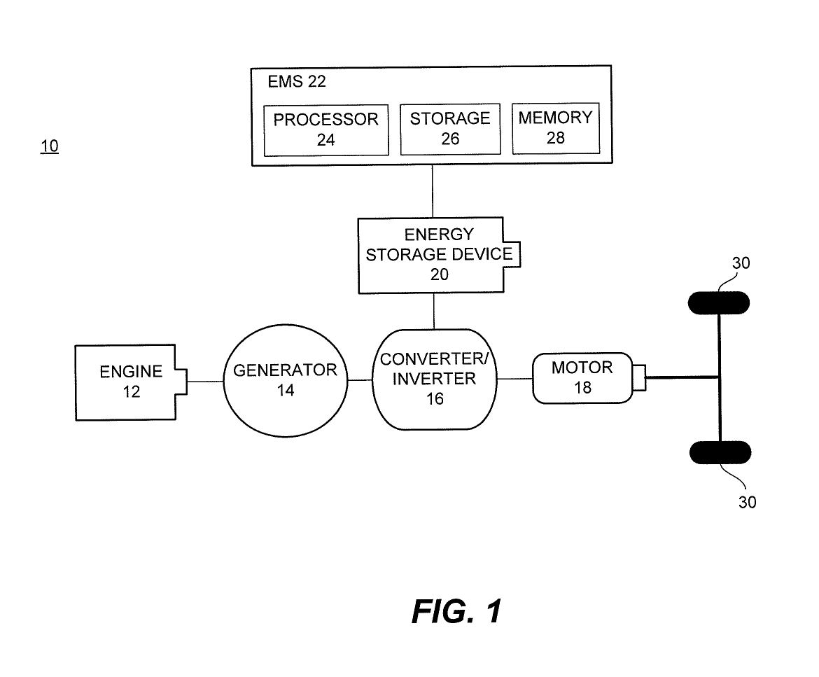

FIG. 1 is a schematic drawing of a hybrid electric drivetrain system 10. Hybrid electric drivetrain system 10 may be included in a fixed or mobile machine that may perform some type of operation associated with a particular industry, such as mining, construction, farming, etc. For example, a fixed machine may include an engine system operating in a plant or off-shore environment (e.g., off-shore drilling platform). Likewise, a mobile machine may include commercial machines, such as excavators, trucks, cranes, mining vehicles, backhoes, material handling equipment, farming equipment, marine vessels, on-highway vehicles, or any other type of earth moving machine. As shown in FIG. 1, hybrid electric drivetrain system 10 may include an engine 12, a generator 14, a converter/inverter 16, an electric motor 18, an energy storage device 20, and an energy management system (EMS) 22.

Engine 12 may be any type of device configured to produce mechanical power to drive generator 14. For example, engine 12 may be a diesel engine, a gasoline engine, a gaseous fuel-powered engine, or any other type of component operable to produce mechanical power.

Generator 14 may be any type of component operable to generate electricity with mechanical power received from engine 12. Generator 14 may also be operable to receive electricity and operate as an electric motor to drive engine 12 for a number of purposes. Generator 14 may be, for example, a permanent-magnet electric machine, a switched reluctance electric machine, a DC electric machine, an induction-type machine or any other type of electric machine known in the art.

Converter/inverter 16 may include various types of controllable electric components for regulating and/or converting electrical power, including, but not limited to, silicon controller rectifiers (SCRs), gate turn-offs (GTOs), insulated gate bipolar transistors (IGBTs), and field-effect transistors (FETs). Converter/inverter 16 may convert AC power from generator 14 to DC power, which may be provided to electric motor 18. Converter/inverter 16 may also receive the DC power from a DC bus and convert the DC power back to AC power while generator 14 provides mechanical energy back onto engine 12.

Electric motor 18 may operate in both a motoring mode to supply mechanical energy to drive the machine and a generating mode to provide regenerative energy. The input of electric motor 18 may be connected to converter/inverter 16 using, for example, IGBT technology. The output of electric motor 18 may be connected to provide propulsive force to, for example, tires 30 of the machine.

Energy storage device 20 may be any type of device operable to store electrical energy and exchange electricity with, i.e., receive electricity from and deliver electricity to, hybrid electric drivetrain system 10. Energy storage device 20 may be one or more of symmetric capacitors such as Electrolytic Capacitor and Ultra-Capacitor, asymmetric capacitors such as Lithium-Ion Capacitor or Nickel-based Capacitor also known as Super Capacitor or Pseudo Battery, and various electrochemical energy storage devices such as Lithium-ion battery and its various forms and compositions, Nickel-based battery, or Lead-Acid based battery, or other similar battery system. Energy storage device 20 may be used to store energy supplied by electric motor 18 and generator 14, and to provide electrical energy to drive electric motor 18. Although FIG. 1 shows hybrid electric drivetrain system 10 including only one energy storage device 20, those skilled in the art will appreciate that multiple energy storage devices may be included in hybrid electric drivetrain system 10.

EMS 22 may manage the energy flows into and out of energy storage device 20. To do so, EMS 22 may estimate the available discharging energy of energy storage device 20, and may regulate the amount of energy drawn from energy storage device 20 such that the energy drawn from energy storage device 20 does not exceed the estimated available discharging energy. EMS 22 may also estimate the acceptable charging energy of energy storage device 20, and may regulate the amount of energy supplied by generator 14 and electric motor 18 to energy storage device 20 such that the amount of supplied energy does not exceed the estimated acceptable charging energy. The term “available discharging energy” refers to the amount of energy energy storage device 20 can discharge from an instantaneous operating point to a lower operating limit, and the term “acceptable charging energy” refers to the amount of energy energy storage device 20 can receive from an instantaneous operating point to an upper operating limit.

EMS 22 may include processor 24, storage 26, and memory 28, included together in a single device and/or provided separately. Processor 24 may include one or more known processing devices, such as a microprocessor from the Pentium™ or Xeon™ family manufactured by Intel™, the Turion™ family manufactured by AMD™, or any other type of processor. Memory 28 may include one or more storage devices configured to store information used by EMS 22 to perform certain functions related to the disclosed embodiments. Storage 26 may include a volatile or non-volatile, magnetic, semiconductor, tape, optical, removable, nonremovable, or other type of storage device or computer-readable medium. Storage 26 may store programs and/or other information, such as information related to processing data received from one or more sensors, such as a voltage sensor, a current sensor, and a temperature sensor, as discussed in greater detail below. Storage 26 may include one or more data structures, such as, for example, one or more maps, which may include multi-dimensional arrays or lookup tables. The maps may contain data in the form of equations, tables, or graphs.

EMS 22 may calculate the available discharging energy and/or the acceptable charging energy of energy storage device 20. In some embodiments, EMS 22 may include one or more tables and/or equations that define relationships between the capacity of energy storage device 20, the state of charge of energy storage device 20, and the amount of electrical energy that energy storage device 20 can receive or discharge. Such tables and/or equations may also factor in one or more other parameters, such as the temperature of energy storage device 20, the present terminal voltage of energy storage device 20, and/or the present discharging current or charging current of energy storage device 20. Methods that EMS 22 may use to determine the available discharging energy and/or the acceptable charging energy of energy storage device 20 are discussed in greater detail below.

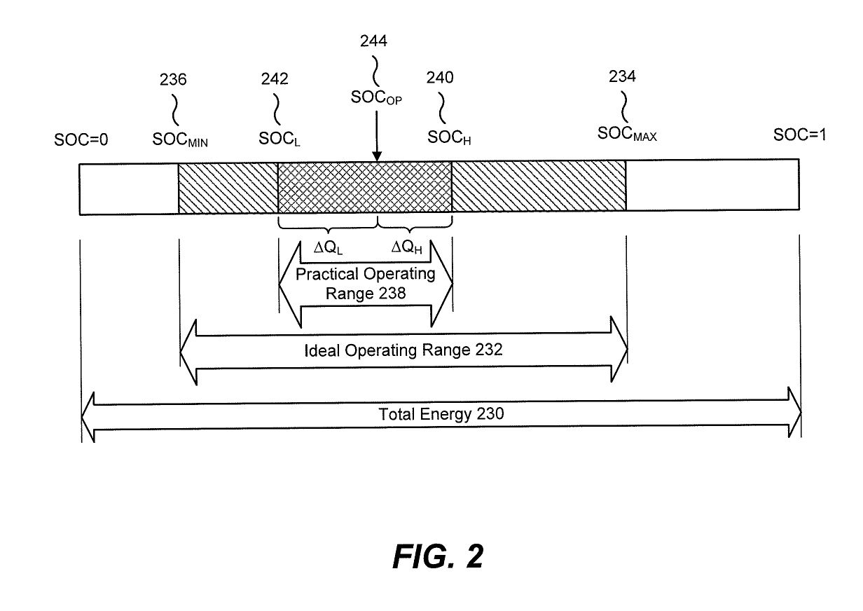

In an exemplary embodiment, before determining the available discharging energy and the acceptable charging energy of energy storage device 20, EMS 22 may determine the operating range of energy storage device 20. FIG. 2 shows an exemplary operating range of energy storage device 20 in terms of state of charge (SOC) of energy storage device 20. The SOC is defined as an available capacity of energy storage device 20 and may be represented as a percentage value. That is, when energy storage device 20 is fully charged, the SOC value of energy storage device 20 may be 100%, and when energy storage device 20 is fully discharged, the SOC value of energy storage device 20 may be 0%.

According to FIG. 2, the total energy 230 stored in energy storage device 20 may be represented by a SOC value equal to 100%, which may be represented in decimal format as 1. An ideal operating range 232 of energy storage device 20 may be bounded by SOC_{MAX} 234 and SOC_{MIN} 236. Under normal circumstances, however, the operating range of energy storage device 20 may be further constrained by practical limitations of hybrid electric drivetrain system 10 in which energy storage device 20 is disposed. For example, hybrid electric drivetrain system 10 may have maximum and minimum system voltage limits, or a maximum discharging current due to cable size and/or heat removal capability. As a result, energy storage device 20 may only be operated in a practical operating range 238 defined by SOC_{H} 240 and SOC_{L} 242, that may be respectively determined in a case-by-case basis depending on the overall system design. In some exemplary embodiments, the value of SOC_{H} 240 may be kept at or below 100% for an ultra-capacitor and at or below 80-90% for a battery cell in order to minimize irreversible damage that leads to significant reduction in service life. The value of SOC_{L} 242 may be determined from the system-level constraints such as system voltage, current, energy efficiency and/or overall heat dissipation capability. The value of SOC_{L} 242 may be around 50% for the ultra-capacitor and around 20% for the battery cell. SOC_{OP} 244 indicates an instantaneous operating point of energy storage device 20 in terms of an instantaneous SOC value of energy storage device 20. As shown in FIG. 2, it may be desirable to maintain SOC_{OP} 244 within practical operating range 238.

In the present disclosure, the instantaneous operating point and operating limits of energy storage device 20 may be represented as different instantaneous SOC values of energy storage device 20. However, those skilled in the art will appreciate that each one of the instantaneous operating point and the operating limits may also be represented as other parameters of energy storage device 20, such as the open circuit voltage of energy storage device 20. For example, an instantaneous operating point of energy storage device 20 may be represented as SOC_{OP} 244 of 80% for a particular ultra-capacitor, and may also be represented as an open circuit voltage of 2.0V for the particular ultra-capacitor.

After determining SOC_{H} 240 and SOC_{L} 242 for practical operating range 238 of energy storage device 20, EMS 22 may estimate the available discharging energy of energy storage device 20. In certain embodiments, the available discharging energy at any instantaneous operating point may be quantified by a series of characteristic curves. Ideally, the amount of available discharging energy of energy storage device 20 between SOC_{MIN} and SOC_{MAX} is equal to the change in absolute energy of energy storage device 20 between SOC_{MIN} and SOC_{MAX}. For an ultra-capacitor, the change in absolute energy may be expressed in terms of equilibrium (or open-circuit) voltages, V_{MIN} and V_{MAX}, measured at the corresponding states:

$${E}_{AVAILABLE\_IDEAL} = \frac{1}{2} C ( {V}_{MAX}^{2} - {V}_{MIN}^{2} ) \qquad ( 1 )$$

Under ideal conditions, the available discharging energy for any discharging power would be identical providing that the energy is drawn from energy storage device 20 from SOC_{MAX} down to SOC_{MIN}, according to Equation (1).

In an actual system, however, when energy storage device 20 delivers power to an external load, the total available discharge energy diminishes due to inefficiency of energy conversion and presence of internal resistance. When energy storage device 20 is discharged at a constant discharging power, the terminal voltage of energy storage device 20 drops due to two main factors: (1) decrease in relative potential across the electrodes of energy storage device 20 due to depletion of energy storage device 20, and (2) ohmic resistance of energy storage device 20. As the terminal voltage drops, the discharging current of energy storage device 20 increases in order to maintain the constant discharging power. The increase in the discharging current leads to a steeper drop in the terminal voltage, which in turns further increases the discharging current. Therefore, unlike the ideal available discharging energy calculated by using only the equilibrium voltages in Equation (1), the actual available discharging energy can vary significantly depending on the discharging power. Thus, the actual available discharging energy may be represented as a cumulative discharging energy calculated based on time-integral of the product of the terminal voltage and discharging current (V×I), which will be described in greater detail below.

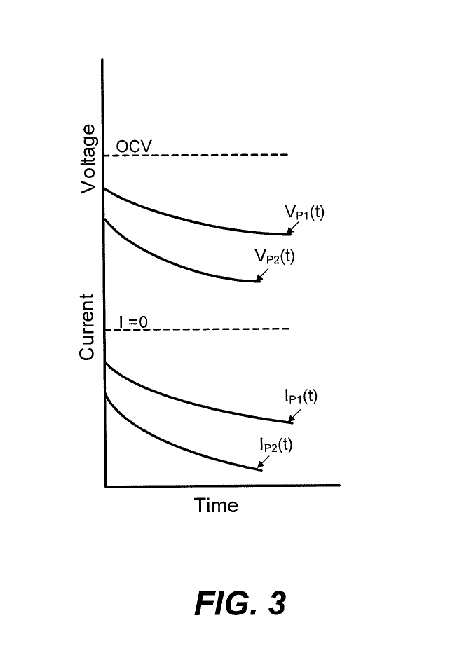

FIG. 3 is a graphical illustration of exemplary terminal voltage and discharging current profiles of energy storage device 20 during a constant-power discharge period from SOC_{OP} to SOC_{L}. As shown in FIG. 3, I_{P1}(t) and I_{P2}(t) are time-varying discharging currents measured at constant discharging power of P₁ and P₂, respectively, and V_{P1}(t) and V_{P2} (t) are time-varying terminal voltages measured at constant discharging power of P₁ and P₂, respectively. Based on the terminal voltage and the discharging current, an instantaneous SOC value and a cumulative discharging energy may be calculated.

The instantaneous SOC value SOC_{OP} may be determined by the value of SOC_{L} and the change in the SOC value of energy storage device 20, i.e., ΔSOC, during the constant-power discharge period, that is,

$${SOC}_{OP} = {SOC}_{L} - Δ SOC = {SOC}_{L} - \frac{Δ {Q}_{L}}{{Q}_{TOTAL}} \qquad ( 2 )$$

where ΔQ_{L} is electric charge removed from energy storage device 20 from SOC_{OP} to SOC_{L}, as shown in FIG. 2, and Q_{TOTAL} is the total electric charge of energy storage device 20. ΔQ_{L} may be determined as the time-integral of the discharging current, that is,

ΔQ_{L}=∫₀^{t}^{₁}I_{P1}(t)dt=∫₀^{t}^{₂}I_{P2}(t)dt= . . . (3)

where t₁, t₂ . . . are discharging times used to discharge energy storage device 20 from SOC_{OP} to SOC_{L} at the constant discharging power of P₁, P₂, . . . , respectively.

At the end of the discharge period, the cumulative discharging energies for the constant discharging power of P₁, P₂, . . . , may be given by

ΔE_{P1}=∫₀^{t}^{₁}V_{P1}(t)I_{P1}(t)dt=∫₀^{t}^{₂}P₁dt=P₁·t₁

ΔE_{P2}=∫₀^{t}^{₂}V_{P2}(t)I_{P2}(t)dt=∫₀^{t}^{₂}P₂dt=P₂·t₂

.

.

. (4)

The cumulative discharging energies calculated according to Equation (4) may represent the available discharging energies at SOC_{OP} for the constant discharging power of P₁, P₂, . . . , respectively. Then, based on Equations (2)-(4), a correlation between available discharging energy and discharging power at different instantaneous operating points SOC_{OP} may be derived.

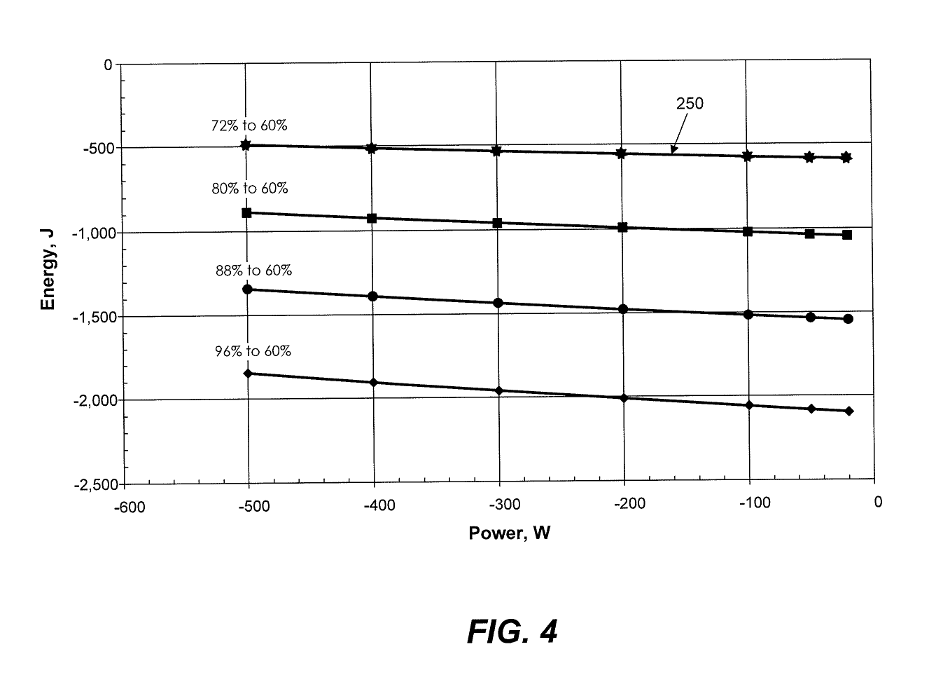

FIG. 4 is an exemplary simulation result showing a correlation between the available discharging energy and the discharging power at different instantaneous operating point SOC_{OP} of 72%, 80%, 88%, and 96%, each for SOC_{L} of 60%. According to data line 250 in FIG. 4, for example, if energy storage device 20 is discharged from SOC_{OP} of 72% to SOC_{L} of 60% at a constant discharging power of −500 W, the available discharging energy of energy storage device 20 would be −500 J; and if energy storage device 20 is discharged from SOC_{OP} of 72% to SOC_{L} of 60% at a constant discharging power of −100 W, the available discharging energy of energy storage device 20 would be −600 J.

Although FIG. 4 only shows discrete values of available discharging energy at different SOC_{OP} of 72%, 80%, 88%, and 96%, and different discharging power of −500 W, −400 W, −300 W, −200 W, −100 W, −50 W, and −10 W, those skilled in the art will appreciate that the available discharging energy between those values may be estimated by, for example, linear interpolation and/or extrapolation based on those discrete values. For example, an available discharging energy at an SOC_{OP} of 75% and a discharging power of −500 W may be estimated by linear interpolation based on the respective available discharging energies at SOC_{OP} of 72% and 80% and discharging power of −500 W.

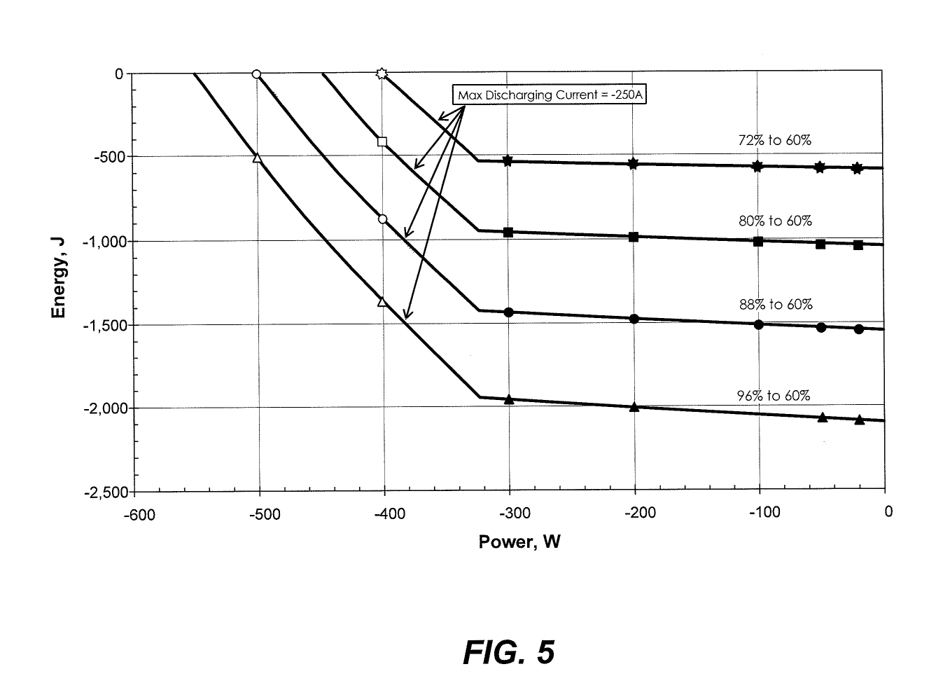

In some embodiments, when energy storage device 20 is disposed within an actual hybrid electric drivetrain system 10, it may not be able to provide the available discharging energy estimated according to Equation (4), due to practical and/or physical limits of the system. For example, for a constant discharging power of −500 W, the discharging current obtained through simulation increases continuously as the terminal voltage decreases. However, energy storage device 20 may have a maximum discharging current limit of −250 A even when the terminal voltage further decreases. Therefore, the calculation of the available discharging energy may be modified considering the maximum discharging current limit of −250 A. For example, the available discharging energy of energy storage device 20 at SOC_{OP} for a constant discharging power of P₁, may be given by

$$\begin{matrix}{E}_{P 1} = {\int }_{0}^{{t}^{′}} {V}_{P 1} ( t ) {I}_{P 1} ( t ) d t + {\int }_{{t}^{′}}^{{t}_{1}} {V}_{P 1} ( t ) {I}_{MAX} d t \\ = {P}_{1} \cdot {t}^{′} + {\int }_{{t}^{′}}^{{t}_{1}} {V}_{P 1} ( t ) {I}_{MAX} d t\end{matrix} \qquad ( 5 )$$

where t′ is the time when the discharging current reaches the maximum discharging current limit I_{MAX}. FIG. 5 shows a revised correlation between available discharging energy and discharging power at different instantaneous operating points, by imposing the maximum discharging current limit of −250 A. Additionally, such practical limits as minimum system voltage of hybrid electric drivetrain system 10 and maximum temperature of energy storage device 20 may also be considered when developing the final correlation between available discharging energy and discharging power at different instantaneous operating points.

The correlation between available discharging energy and constant discharging power at different instantaneous operating points may be stored in storage 26 of EMS 22, so that EMS 22 may determine the available discharging energy of energy storage device 20 throughout the machine operation cycle. In one embodiment, different available discharging energy values as a function of SOC_{OP} and constant discharging power may be stored in storage 26 in the form of one or more maps or look-up tables.

In some embodiments, EMS 22 may also determine an acceptable charging energy in energy storage device 20 at an instantaneous operating point. The acceptable charging energy represents the ability of energy storage device 20 to capture the energy generated from electric motor 18 or engine 12. Similar to the available discharge energy calculation introduced in the foregoing paragraphs, the amount of acceptable charging energy may be represented by a series of characteristic curves.

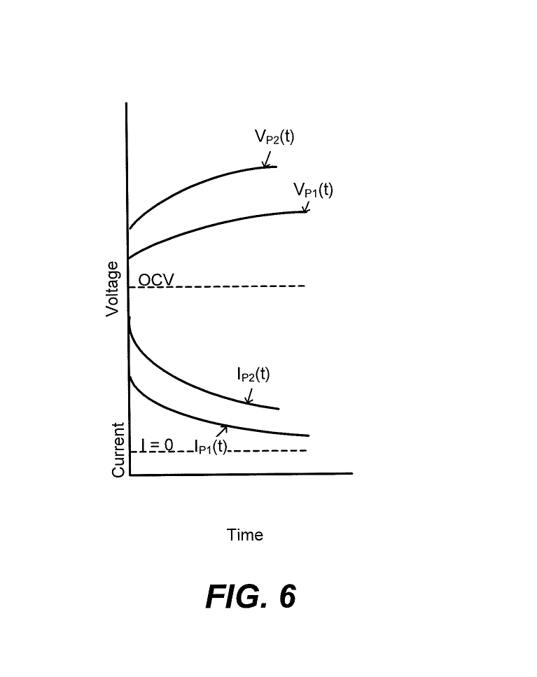

FIG. 6 schematically illustrates terminal voltage and charging current profiles of energy storage device 20 during a constant-power charge period from the instantaneous operating point SOC_{OP} to SOC_{H}. As shown in FIG. 6, I_{P1}(t) and I_{P2}(t) are the time-varying charging current measured at constant charging power of P₁ and P₂, respectively, and V_{P1}(t) and V_{P2} (t) are the time-varying terminal voltage measured at constant charging power of P₁ and P₂, respectively. Based on the terminal voltage and the charging current, an instantaneous SOC value and a cumulative charging energy may be calculated.

The instantaneous SOC value SOC_{OP} may be determined by the value of SOC_{H} and the increase in the SOC value of energy storage device 20, i.e., ΔSOC, during the constant-power charge period, that is,

$${SOC}_{OP} = {SOC}_{H} - Δ SOC = {SOC}_{H} - \frac{Δ {Q}_{H}}{{Q}_{TOTAL}} \qquad ( 6 )$$

where ΔQ_{H} is the electric charge accepted in energy storage device 20 from SOC_{OP} to SOC_{H}, as shown in FIG. 2, and Q_{TOTAL} is the total charge of energy storage device 20. ΔQ_{H} may be expressed in terms of the time integral of the charging current as,

ΔQ_{H}=∫₀^{t}^{₁}I_{P1}(t)dt=∫₀^{t}^{₂}I_{P2}(t)dt= . . . (7)

where t₁, t₂ . . . are the charging times used to charge energy storage device 20 from SOC_{OP} to SOC_{H} at the constant charging power of P₁, P₂, . . . , respectively.

At the end of the charging period, the cumulative charging energies for the constant charging power of P₁, P₂, . . . , may be given by

ΔE_{P1}=∫₀^{t}^{₁}V_{P1}(t)I_{P1}(t)dt=∫₀^{t}^{₂}P₁dt=P₁·t₁

ΔE_{P2}=∫₀^{t}^{₂}V_{P2}(t)I_{P2}(t)dt=∫₀^{t}^{₂}P₂dt=P₂·t₂

.

.

. (8)

The cumulative charging energies calculated according to Equation (8) may represent the acceptable charging energies at SOC_{OP} for the constant charging power of P₁, P₂, . . . , respectively. Then, based on Equations (6)-(8), a correlation between acceptable charging energy and charging power at different instantaneous operating points may be derived.

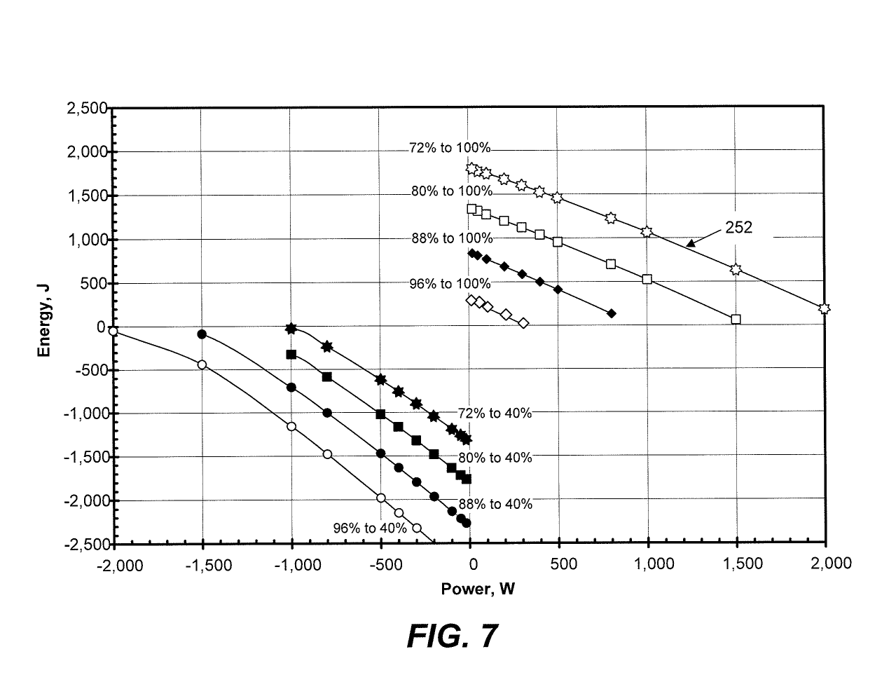

FIG. 7 is an exemplary simulation result showing a correlation between the acceptable charging energy and the charging power at different instantaneous operating point SOC_{OP} of 72%, 80%, 88%, and 96% each for SOC_{H} of 100%, and between the available discharging energy and discharging power at different instantaneous operating points SOC_{OP} of 72%, 80%, 88%, and 96%, each for SOC_{L} of 40%. According to data line 252 of FIG. 7, for example, if energy storage device 20 is charged from SOC_{OP} of 72% to SOC_{L} of 100% at a constant charging power of 1500 W, energy storage device 20 would accept a total energy of 600 J; and if energy storage device 20 is charged from SOC_{OP} of 72% to SOC_{H} of 100% at a constant charging power of 500 W, energy storage device 20 would accept a total energy of about 1400 J.

Similar to the limitations discussed in the previous paragraphs, practical limits such as maximum charging current, maximum system voltage, and/or maximum cell temperature may also be considered. Similarly, the correlation between the acceptable charging energy and the charging power at different operating points may be stored in storage 26.

In some embodiments, based on the available discharging energy and the acceptable charging energy calculated as described above, EMS 22 may calculate the overall efficiency of energy storage device 20. The overall efficiency of energy storage device 20 is defined based on the amount of energy being discharged from or charged to energy storage device 20. For example, a discharge energy efficiency η_{D} at an instantaneous operating point SOC_{OP} for a discharging power may be defined as the ratio of the available discharging energy of energy storage device 20 at SOC_{OP} for the discharging power to the change in absolute energy of energy storage device 20 during a discharge period from SOC_{OP} (t=t₀) to SOC_{L} (t=t). Thus, the discharge energy efficiency η_{D} at SOC_{OP} for the discharging power may be determined by,

$${η}_{D} = \frac{{E}_{AVAILABLE}}{Δ {E}_{ABSOLUTE}} \qquad ( 9 )$$

η_{D} represents the conversion efficiency during the entire discharge period. In Equation (9), E_{AVAILABLE} is the available discharging energy calculated according to Equation (4) or (5), and ΔE_{ABSOLUTE} is the change in the absolute energy from SOC_{OP} (t=t₀) to SOC_{L} (t=t).

ΔE_{ABSOLUTE} of energy storage device 20 during the discharge period from SOC_{OP} to SOC_{L} may be calculated by,

$$Δ {E}_{ABSOLUTE} = {\sum }_{{SOC}_{L}}^{{SOC}_{OP}} \frac{1}{2} {C}_{SOC} ( {V}_{{OC}_{SOC + δ}}^{2} - {V}_{{OC}_{SOC - δ}}^{2} ) \qquad ( 10 )$$

where C_{SOC} is the capacitance of energy storage device 20 for a particular SOC value of SOC, V_{OC}_{_{SOC+δ}} is the open circuit voltage of energy storage device 20 for a particular SOC value of SOC+δ, and V_{OC}_{_{SOC−δ}} is the open circuit voltage of energy storage device 20 for a particular SOC value of SOC−δ.

In some embodiments, when energy storage device 20 is a battery, C_{SOC} in Equation (10) may be represented by,

$${C}_{SOC} \approx \frac{{Q}_{SOC + δ} - {Q}_{SOC - δ}}{{V}_{{OC}_{SOC + δ}} - {V}_{{OC}_{SOC - δ}}} \qquad ( 11 )$$

where Q_{SOC+δ} is the electric charge of energy storage device 20 for a particular SOC value of SOC+δ, and Q_{SOC-δ} is the electric charge of energy storage device 20 for a particular SOC value of SOC−δ. In addition, Q_{SOC+δ}−Q_{SOC-δ} may be represented by,

Q_{SOC+δ}−Q_{SOC-δ}=Q_{TOTAL}(SOC_{δ}−SOC_{δ}_{^{−}}) (12)

where SOL_{δ}_{⁺} is the SOC value of energy storage device 20 at time δ⁺, and SOL_{δ}_{^{−}} is the SOC value of energy storage device 20 at time δ⁻, and Q_{TOTAL} is the total charge of energy storage device 20. Based on Equations (11) and (12), Equation (10) may be derived to read,

$$Δ {E}_{ABSOLUTE} \approx {Q}_{TOTAL} {\int }_{{SOC}_{OP}}^{{SOC}_{L}} {V}_{{OC}_{SOC}} d SOC \qquad ( 13 )$$

where V_{OC}_{_{SOC}} is the open circuit voltage of energy storage device 20 for a particular SOC value.

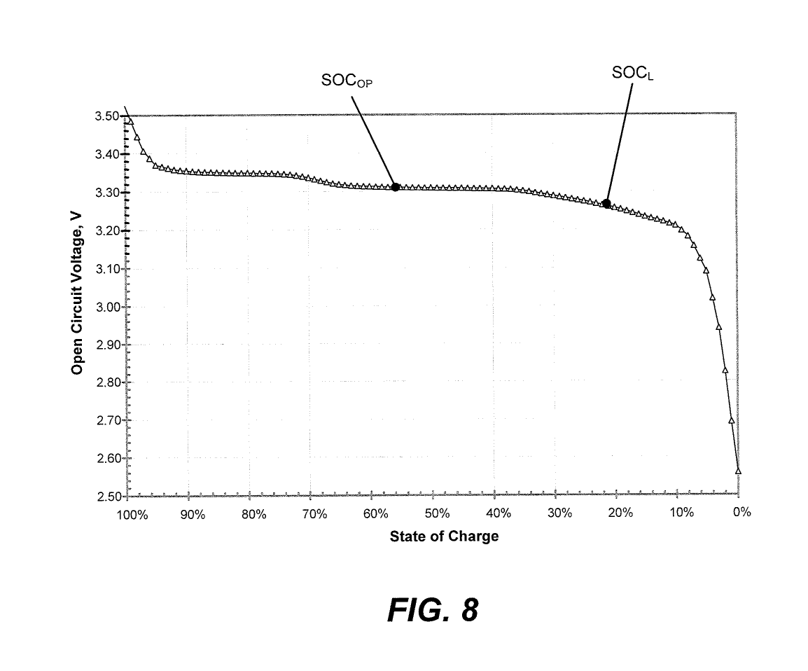

According to Equation (13), ΔE_{ABSOLUTE} of energy storage device 20 may be determined based on an open circuit voltage (i.e., equilibrium voltage) versus SOC curve of energy storage device 20. In order to obtain the open circuit voltage versus SOC curve, energy storage device 20 may be discharged from an SOC of 100% to an SOC of 0%. For each step during the discharge period, energy storage device 20 is kept disconnected from any circuit for a predetermined time, for example, 24 hours, and the difference of electrical potential between two terminals of energy storage device 20 is measured and recorded as the open circuit voltage. FIG. 8 is a graphical illustration of an exemplary open circuit voltage versus SOC curve of a battery, that may be obtained according to embodiments of the present disclosure. According to Equation (13), ΔE_{ABSOLUTE} of energy storage device 20 during the discharge period from SOC_{OP} to SOL_{L} may be represented by the area under the open circuit voltage versus SOC curve between SOC_{OP} and SOC_{L}.

In some embodiments, when energy storage device 20 is an ultra-capacitor in which C_{SOC} is constant, and the open circuit voltage changes substantially linearly as a function of the SOC value, the absolute energy of the ultra-capacitor may be expressed in terms of open circuit voltages. Therefore, Equation (10) may be derived by,

$$Δ {E}_{ABSOLUTE} = \frac{1}{2} C ( {V}_{OC}^{2} ( t ) - {V}_{OC}^{2} ( {t}_{0} ) ) \qquad ( 14 )$$

where V_{OC}(t) is the open circuit voltage of the ultra-capacitor determined at time t, and V_{OC}(t₀) is the open circuit voltage of the ultra-capacitor determined at time t₀.

For a small time duration (t−t₀=Δt→0), an intermediate discharge energy efficiency η*_{D} may be expressed in terms of instantaneous power rather than the cumulative energy as

$${η}_{D}^{*} \approx \frac{V ( {t}_{0}^{+} ) I ( {t}_{0}^{+} )}{{V}_{EQM} ( {t}_{0}^{+} ) I ( {t}_{0}^{+} )} = \frac{V ( {t}_{0}^{+} )}{{V}_{EQM} ( {t}_{0}^{+} )} \qquad ( 15 )$$

where t₀⁺=t₀+Δt for Δt→0.

Similarly, the charge energy efficiency η_{C} at an instantaneous operating point SOC_{OP} for a charging power may be defined as the ratio of the acceptable charging energy of energy storage device 20 at SOC_{OP} for the charging power to the change in absolute energy of energy storage device 20 during a charge period from SOC_{OP} (t=t₀) to SOC_{H} (t=t). The charge energy efficiency η_{C} at SOC_{OP} for the charging power may be determined by,

$${η}_{C} = \frac{Δ {E}_{ABSOLUTE}}{{E}_{ACCEPTABLE}} \qquad ( 16 )$$

η_{C} represents the conversion efficiency during the complete charge period. In Equation (16), E_{ACCEPTABLE} is the acceptable charging energy calculated according to in Equation (8), and ΔE_{ABSOLUTE} is the change in the absolute energy from SOC_{OP}(t=t₀) to SOC_{H} (t=t), and may be represented by,

$$Δ {E}_{ABSOLUTE} = {\sum }_{{SOC}_{OP}}^{{SOC}_{H}} \frac{1}{2} {C}_{SOC} ( {V}_{{OC}_{SOC + δ}}^{2} - {V}_{{OC}_{SOC - δ}}^{2} ) \qquad ( 17 )$$

When energy storage device 20 is a battery, ΔE_{ABSOLUTE} from SOC_{OP}(t=t₀) to SOC_{H} (t=t) may be calculated according to the open circuit voltage versus SOC curve, by,

$$Δ {E}_{ABSOLUTE} = {Q}_{TOTAL} {\int }_{{SOC}_{OP}}^{{SOC}_{H}} {V}_{OC} d SOC \qquad ( 18 )$$

For a small time duration (t−t₀=Δt→0), an intermediate charge energy efficiency η*_{C} can be expressed in terms of instantaneous power (rather than cumulative energy) as

$${η}_{C}^{*} \approx \frac{{V}_{EQM} ( {t}_{0}^{+} ) I ( {t}_{0}^{+} )}{V ( {t}_{0}^{+} ) I ( {t}_{0}^{+} )} = \frac{{V}_{EQM} ( {t}_{0}^{+} )}{V ( {t}_{0}^{+} )} . \qquad ( 19 )$$

In some embodiments, EMS 22 may determine a round-trip efficiency of energy storage device 20 based on the charge and discharge energy efficiencies as described above. By definition, the round-trip efficiency is the ratio of the usable output energy (E_{OUT}) to the input energy required to return to the same charge state (E_{IN}). That is, the round-trip efficiency may be expressed by:

$$\begin{matrix}{η}_{RTrip} = \vert \frac{{E}_{OUT}}{{E}_{IN}} \vert \\ = \vert \frac{{\int }_{0}^{t} V ( t ) I ( t ) d t}{{\int }_{0}^{{t}^{*}} V ( t ) I ( t ) d t} \vert \\ = {η}_{D} \times {η}_{C}\end{matrix} \qquad ( 20 )$$

wherein t is the time used to discharge energy storage device 20 from a first state to a second state, and t* is the time used to charge energy storage device 20 back from the second state to the first state. According to Equation (20), EMS 22 may determine the round-trip efficiency based on the discharge energy efficiency and the charge energy efficiency calculated according to Equations (9) and (16), respectively.

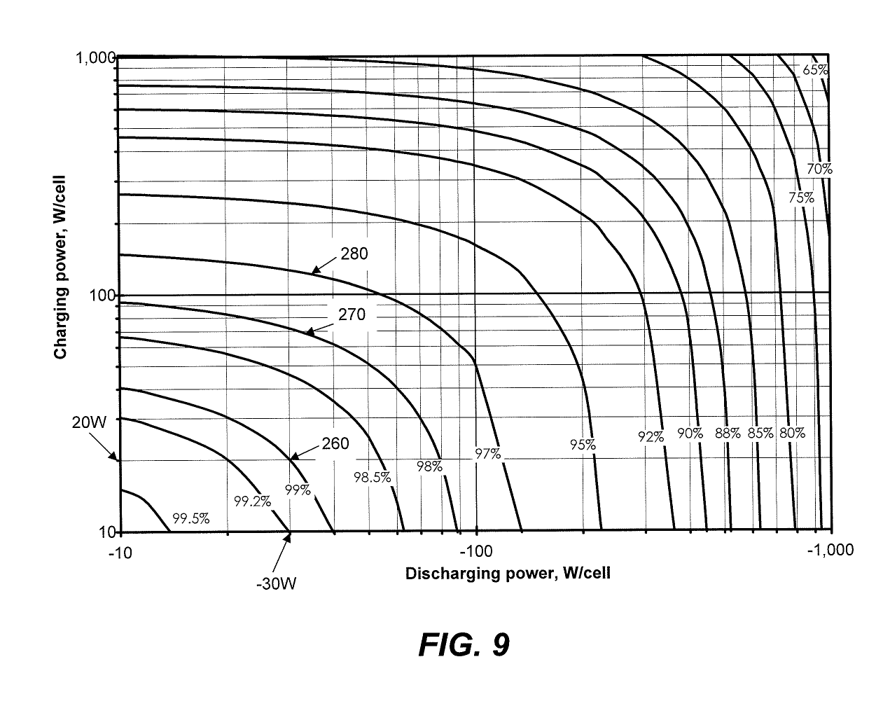

FIG. 9 is a graph showing exemplary estimated round-trip efficiencies corresponding to different discharging and charging powers for energy storage device 20 at a SOC of 80%. For example, according to data curve 260 of FIG. 9, when energy storage device 20 is discharged at a constant discharging power of −30 W from SOC of 80.0%, and charged at a constant charging power of 20 W to SOC of 80.0%, the round-trip efficiency is about 99%.

FIG. 9 shows discrete data curves representing the estimated round-trip efficiencies corresponding to different constant discharging powers and constant charging powers. The round-trip efficiencies between the discrete data curves may be obtained by using linear interpretation based on the immediate adjacent data curves. For example, when energy storage device 20 is discharged at a constant discharging power of −30 W from SOC of 80.0%, and charged at a constant charging power of 100 W to SOC of 80.0%, the round-trip efficiency may be estimated based on data curves 270 and 280 that correspond to round-trip efficiencies of 98% and 97%, respectively. Using linear interpretation from 98% and 97%, the round-trip efficiency may be about 97.5%.

### INDUSTRIAL APPLICABILITY

The disclosed EMS 22 may be applicable to any machine where accurate characterization of the machine's energy storage device is desired. It may prove valuable during operation of hybrid electric drivetrain system 10 to have an accurate estimation of how much discharging current and power the system can withdraw from or supply to energy storage device 20, as well as how much energy storage device 20 can supply or receive at any given point in time.

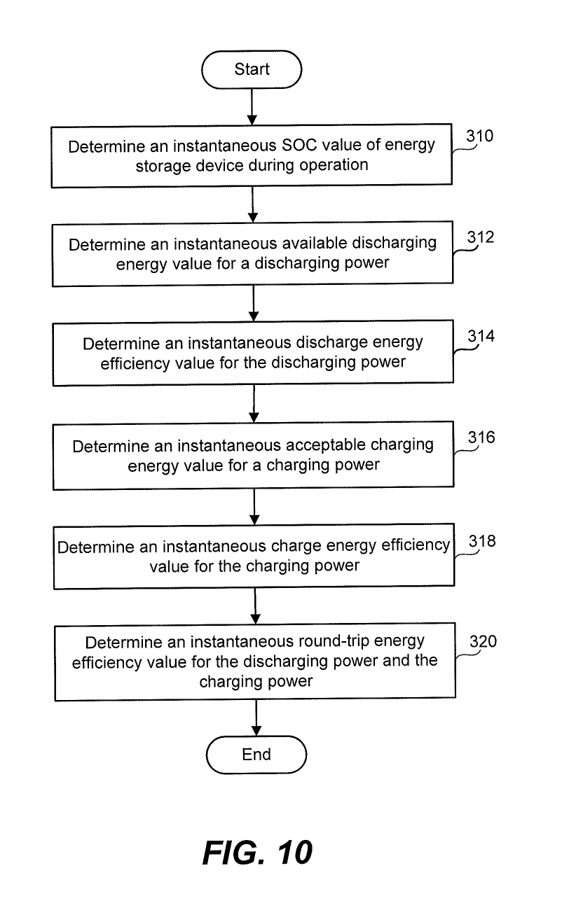

FIG. 10 is a flowchart depicting an exemplary method used by EMS 22 for characterizing energy storage device 20.

In Step 310, EMS 22 may determine an instantaneous SOC value of energy storage device 20 during operation of energy storage device 20. For example, the instantaneous SOC value of energy storage device 20 may be calculated based on Equations (2) and (3) during a discharge period of energy storage device 20, or Equations (6) and (7) during a charge period of energy storage device 20.

In Step 312, EMS 22 may determine an instantaneous available discharging energy value for a discharging power. For example, the instantaneous available discharging energy value may be retrieved from a first map based on the discharging power and the determined instantaneous SOC value. The first map may correlate each of a plurality of available discharging energy values of energy storage device 20 to a combination of one of a plurality of discharging powers of energy storage device 20 and one of a plurality of SOC values of energy storage device 20.

In Step 314, EMS 22 may determine an instantaneous discharge energy efficiency value for the discharging power. For example, the instantaneous discharge energy efficiency value may be retrieved from a second map based on the discharging power and the determined instantaneous SOC value. The second map may correlate each of a plurality of discharge energy efficiency values of energy storage device 20 to a combination of one of a plurality of discharging powers of energy storage device 20 and one of a plurality of SOC values of energy storage device 20.

In Step 316, EMS 22 may determine an instantaneous acceptable charging energy value for a charging power. For example, the instantaneous acceptable charging energy value may be retrieved from a third map based on the charging power and the determined instantaneous SOC value. The third map may correlate each one of a plurality of acceptable charging energy values of energy storage device 20 to a combination of one of a plurality of charging powers of energy storage device 20 and one of a plurality of SOC values of energy storage device 20.

In Step 318, EMS 22 may determine an instantaneous charge energy efficiency value for the charging power. For example, the instantaneous charge energy efficiency value may be retrieved from a fourth map based on the charging power and the determined instantaneous SOC value. The fourth map may correlate each of a plurality of charge energy efficiency values of energy storage device 20 to a combination of one of a plurality of charging powers of energy storage device 20 and one of a plurality of SOC values of energy storage device 20.

In Step 320, EMS 22 may determine an instantaneous round-trip energy efficiency value for the discharging power and the charging power. For example, the instantaneous round-trip energy efficiency value may be retrieved from a fifth map based on the discharging power, the charging power and the determined instantaneous SOC value. The fifth map may correlates each one of a plurality of round-trip energy efficiency values of energy storage device 20 to a combination of one of a plurality of discharging powers of energy storage device 20, one of a plurality of charging powers of energy storage device 20, and one of a plurality of SOC values of energy storage device 20.

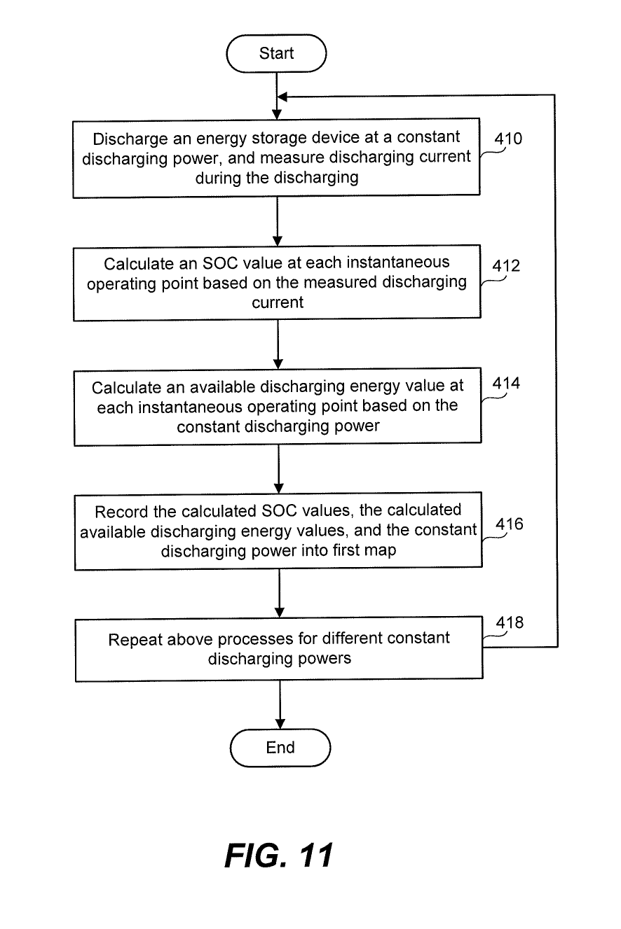

Each one of the first through fifth maps may include multi-dimensional arrays or lookup tables. The maps for energy storage device 20 may be established through physical experiments or computer simulation, e.g., according to the exemplary methods discussed below with regard to FIGS. 11-15. In certain embodiments, the maps may be established before energy storage device 20 is coupled to hybrid electric drivetrain system 10.

FIG. 11 is a flowchart depicting an exemplary method that may be used for establishing the first map for energy storage device 20. In step 410, energy storage device 20 may be discharged at a constant discharging power, and discharging current of energy storage device 20 may be measured during the discharging. For example, energy storage device 20 may be discharged at the constant discharging power from an initial operating point to an end operating point, and the discharging current of energy storage device 20 may be measured at different time steps during the discharging.

In Step 412, an SOC value may be calculated at each instantaneous operating point. In the present specification, the instantaneous operating point is one of a plurality of instantaneous operating points between the initial operating point and the end operating point. For example, the SOC value may be calculated by integrating the discharging currents measured at different time steps from the instantaneous operating point to the end operating point. The SOC value calculated at each instantaneous operating point for the constant discharging power may be represented by:

$${SOC}_{OP} = {SOC}_{L} - \frac{{\int }_{{t}_{OP}}^{{t}_{L}} {I}_{P} ( t ) d t}{{Q}_{TOTAL}} \qquad ( 21 )$$

wherein SOC_{OP} denotes the SOC value at the instantaneous operating point, SOC_{L} denotes the SOC value at the end operating point, I_{P}(t) denotes the discharging current measured at time t during the discharging of energy storage device 20 at the constant discharging power P, t_{OP} denotes the time at the instantaneous operating point, t_{L} denotes the time at the end operating point, and Q_{TOTAL} denotes the total charge of energy storage device 20.

In Step 414, an available discharging energy value may be calculated at each instantaneous operating point based on the constant discharging power. For example, the available discharging energy value may be calculated as a product of the constant discharging power and the time difference between the instantaneous operating point to the end operating point, represented by:

E_{AVAILABLE}=P·(t_{L}−t_{OP}) (22)

wherein E_{AVAILABLE} denotes the available discharging energy value at the instantaneous operating point for the constant discharging power P.

In Step 416, the calculated SOC values, the calculated available discharging energy values, and the constant discharging power may be recorded into the first map. In Step 418, the above processes may be repeated for different constant discharging powers. That is, the steps of discharging energy storage device 20 at Step 410, calculating the SOC values at Step 412, calculating the available discharging energy values at Step 414, and recording the calculated values in the first map at Step 416 may be repeated for different constant discharging powers.

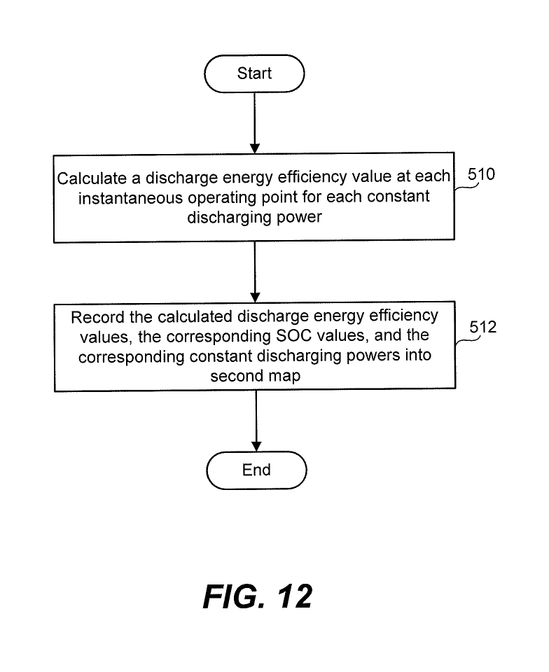

FIG. 12 is a flowchart depicting an exemplary method used for establishing the second map for energy storage device 20. In step 510, a discharge energy efficiency value may be calculated at each instantaneous operating point for each constant discharging power. For example, the discharge energy efficiency value at each instantaneous operating point for the constant discharging power may be calculated by:

$$\begin{matrix}{η}_{D} = \frac{{E}_{AVAILABLE}}{Δ {E}_{ABSOLUTE}} \\ = \frac{{E}_{AVAILABLE}}{{\int }_{{SOC}_{L}}^{{SOC}_{OP}} \frac{1}{2} {C}_{SOC} ( {V}_{{OC}_{SOC + δ}}^{2} - {V}_{{OC}_{SOC - δ}}^{2} )}\end{matrix} \qquad ( 23 )$$

wherein η_{D} denotes the discharge energy efficiency value at the instantaneous operating point, E_{AVAILABLE} denotes a corresponding available discharging energy value, ΔE_{ABSOLUTE} denotes the change in an absolute energy of energy storage device 20 between the instantaneous operating point and the end operating point, C_{SOC} denotes a capacitance of energy storage device 20 measured when an SOC value of energy storage device 20 is SOC, V_{OC}_{_{SOC+δ}} denotes an open circuit voltage of energy storage device 20 measured when an SOC value of energy storage device 20 is SOC+δ, V_{OC}_{_{SOC−δ}} is an open circuit voltage of energy storage device 20 measured when an SOC value of energy storage device 20 is SOC−δ, and δ is an infinitesimal small value. E_{AVAILABLE} may be retrieved from the first map established according the method described previously, based on the constant discharging power and a SOC value of energy storage device 20 at the instantaneous operating point. ΔE_{ABSOLUTE} may be determined based on Equations (13) or (14). In Step 512, the calculated discharge energy efficiency values, the corresponding SOC values, and the corresponding constant discharging powers may be recorded into the second map.

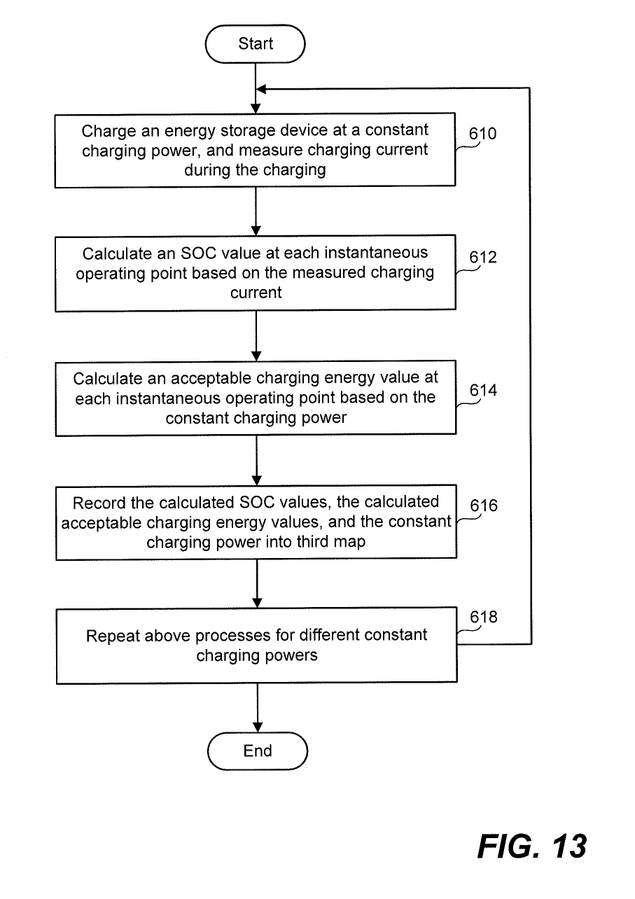

FIG. 13 is a flowchart depicting an exemplary method used for establishing the third map for energy storage device 20. In step 610, energy storage device 20 may be charged at a constant charging power, and charging current of energy storage device 20 may be measured during the charging.

In step 612, a SOC value of energy storage device 20 may be calculated at each instantaneous operating point based on the measured charging current. For example, the SOC value at each instantaneous operating point for the constant charging power may be calculated by:

$${SOC}_{OP} = {SOC}_{H} - \frac{{\int }_{{t}_{OP}}^{{t}_{H}} {I}_{P} ( t ) d t}{{Q}_{TOTAL}} \qquad ( 24 )$$

wherein SOC_{OP} denotes the SOC value at the instantaneous operating point, SOC_{H} denotes the SOC value at the end operating point, I_{P}(t) denotes the charging current measured at time t during the charging of energy storage device 20 at the constant charging power P, t_{OP} denotes the time at the instantaneous operating point, t_{H} denotes the time at the end operating point, and Q_{TOTAL} denotes the total charge of energy storage device 20.

In step 614, an acceptable charging energy value at each instantaneous operating point may be calculated based on the constant charging power. For example, the acceptable charging energy value at each instantaneous operating point for the constant charging power is calculated by:

E_{ACCEPTABLE}=P·(t_{H}−t_{OP}) (25)

wherein E_{ACCEPTABLE} denotes the acceptable charging energy value at the instantaneous operating point for the constant discharging power P.

In Step 616, the calculated SOC values, the calculated acceptable charging energy values, and the constant charging power may be recorded into the third map. In Step 618, the above processes may be repeated for different constant charging powers. That is, the steps of charging energy storage device 20 at Step 610, calculating the SOC values at Step 612, and calculating the acceptable charging energy values at Step 614, and recording the calculated values in the third map at Step 616 may be repeated for different constant charging powers.

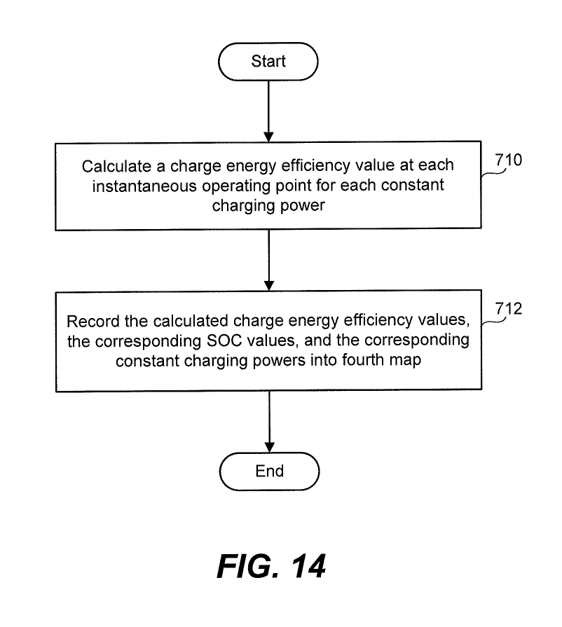

FIG. 14 is a flowchart depicting an exemplary method used for establishing the fourth map for energy storage device 20. In step 710, a charge energy efficiency value may be calculated at each instantaneous operating point for each constant charging power. For example, the charge energy efficiency value at each instantaneous operating point for the constant discharging power may be calculated by:

$$\begin{matrix}{η}_{C} = \frac{Δ {E}_{ABSOLUTE}}{{E}_{ACCEPTABLE}} \\ = \frac{{\sum }_{{SOC}_{OP}}^{{SOC}_{H}} \frac{1}{2} {C}_{SOC} ( {V}_{{OC}_{SOC + δ}}^{2} - {V}_{{OC}_{SOC - δ}}^{2} )}{{E}_{ACCEPTABLE}}\end{matrix} \qquad ( 26 )$$

wherein η_{C} denotes the charge energy efficiency value at the instantaneous operating point, E_{ACCEPTABLE} denotes a corresponding acceptable charging energy value, ΔE_{ABSOLUTE} denotes the change in an absolute energy of energy storage device 20 between the instantaneous operating point and the end operating point, C_{SOC} denotes a capacitance of energy storage device 20 measured when an SOC value of energy storage device 20 is SOC, V_{OC}_{_{SOC+δ}} denotes an open circuit voltage of energy storage device 20 measured when an SOC value of energy storage device 20 is SOC+δ, V_{OC}_{_{SOC−δ}} is an open circuit voltage of energy storage device 20 measured when an SOC value of energy storage device 20 is SOC−δ, and δ is an infinitesimally small value. E_{ACCEPTABLE} may be retrieved from the third map established according the method described previously, based on the constant charging power and a SOC value of energy storage device 20 at the instantaneous operating point. ΔE_{ABSOLUTE} may be determined based on Equations (14) or (18). In Step 712, the calculated charge energy efficiency values, the corresponding SOC values, and the corresponding constant charging powers may be recorded into the fourth map.

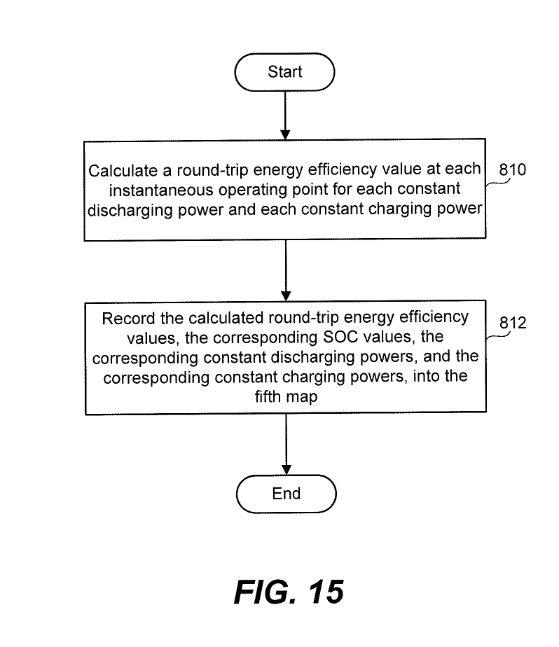

FIG. 15 is a flowchart depicting an exemplary method used for establishing the fifth map for energy storage device 20. In step 810, a round-trip energy efficiency value may be calculated at each instantaneous operating point for each constant discharging power and each charging power. For example, the round-trip energy efficiency value may be calculated based on a corresponding discharge energy efficiency value and a corresponding charge energy efficiency value by:

η_{RTrip}=η_{D}×η_{C} (27)

wherein η_{RTrip} the round-trip energy efficiency value at the instantaneous operating point for the constant discharging power and the constant charging power, η_{D} denotes the corresponding discharge energy efficiency value retrieved from the second map based on the constant discharging power and a SOC value of energy storage device 20 at the instantaneous operating point, and η_{C} denotes the corresponding charge energy efficiency value retrieved from the fourth map based on the constant charging power and the SOC value. In Step 812, the calculated round-trip energy efficiency value, the corresponding SOC values, the corresponding constant discharging powers, and the corresponding constant discharging powers may be recorded into the fifth map.

The present disclosure provides a method for determining available discharging energy and acceptable charging energy of an energy storage device as a function of discharging and charging power, respectively. The determination may be performed during operation of the energy storage device as the SOC of the energy storage device changes continuously during dynamic operating cycle. The determination may be dependent upon the condition under which the energy storage device is applied into a system.

The present disclosure further introduces a method of calculating instantaneous efficiency the energy storage device. Such calculated efficiency values allows the Energy Management System to manage charging and discharging several electrical components (sink and sources) as well as hydraulic components, thus achieving optimal energy distribution.

It will be apparent to those skilled in the art that various modifications and variations can be made to the disclosed system for characterizing an energy storage device. Other embodiments will be apparent to those skilled in the art from consideration of the specification and practice of the disclosed system. It is intended that the specification and examples be considered as exemplary only, with a true scope being indicated by the following claims and their equivalents.

What is claimed is:

1. A computer-implemented method for characterization of an energy storage device, the method comprising:
determining an instantaneous state of charge (SOC) value of the energy storage device during operation of the energy storage device; and
retrieving an instantaneous available discharging energy value of the energy storage device from a first map based on a discharging power of the energy storage device and the determined instantaneous SOC value,
wherein the first map correlates each of a plurality of available discharging energy values of the energy storage device to a combination of one of a plurality of discharging powers of the energy storage device and one of a plurality of SOC values of the energy storage device.

2. The computer-implemented method of claim 1, wherein the first map is established by:
discharging the energy storage device at a constant discharging power from an initial operating point to an end operating point, and measuring discharging current of the energy storage device at different time steps during the discharging;
calculating an SOC value at each of a plurality of instantaneous operating points between the initial operating point and the end operating point, by integrating the discharging currents measured at the different time steps; and
calculating one of the plurality of available discharging energy values at each instantaneous operating point as a product of the constant discharging power and a time difference between the instantaneous operating point and the end operating point.

3. The computer-implemented method of claim 2, wherein the SOC value at each instantaneous operating point for the constant discharging power is calculated by:
$${SOC}_{OP} = {SOC}_{L} - \frac{{\int }_{{t}_{OP}}^{{t}_{L}} {I}_{P} ( t ) d t}{{Q}_{TOTAL}}$$
wherein SOC_{OP} denotes the SOC value at the instantaneous operating point, SOC_{L} denotes the SOC value at the end operating point, I_{P}(t) denotes the discharging current measured at time t during the discharging of the energy storage device, t_{OP} denotes the time at the instantaneous operating point, t_{L} denotes the time at the end operating point, and Q_{TOTAL} denotes the total charge of the energy storage device.

4. The computer-implemented method of claim 2, further including retrieving an instantaneous discharge energy efficiency value of the energy storage device from a second map based on the discharging power and the determined instantaneous SOC value of the energy storage device,
wherein the second map correlates each of a plurality of discharge energy efficiency values of the energy storage device to a combination of one of the plurality of discharging powers of the energy storage device and one of the plurality of SOC values of the energy storage device.

5. The computer-implemented method of claim 4, wherein the second map is established by calculating one of the plurality of discharge energy efficiency values at each instantaneous operating point, by:
$$\begin{matrix}{η}_{D} = \frac{{E}_{AVAILABLE}}{Δ {E}_{ABSOLUTE}} \\ = \frac{{E}_{AVAILABLE}}{{\int }_{{SOC}_{L}}^{{SOC}_{OP}} \frac{1}{2} {C}_{SOC} ( {V}_{{OC}_{SOC + δ}}^{2} - {V}_{{OC}_{SOC - δ}}^{2} )}\end{matrix}$$
wherein η_{D} denotes the discharge energy efficiency value at the instantaneous operating point, E_{AVAILABLE} denotes a corresponding available discharging energy value retrieved from the first map based on the constant discharging power and the SOC value of the energy storage device at the instantaneous operating point, ΔE_{ABSOLUTE} denotes the change in an absolute energy of the energy storage device between the instantaneous operating point and the end operating point, C_{SOC} denotes a capacitance of the energy storage device measured when an SOC value of the energy storage device is SOC, V_{OC}_{_{SOC+δ}} denotes an open circuit voltage of the energy storage device measured when an SOC value of the energy storage device is SOC+δ, V_{OC}_{_{SOC−δ}} is an open circuit voltage of the energy storage device measured when an SOC value of the energy storage device is SOC−δ, and δ is an infinitesimal small value.

6. The computer-implemented method of claim 1, further including retrieving an instantaneous acceptable charging energy value of the energy storage device from a third map based on a charging power and the determined instantaneous SOC value of the energy storage device,
wherein the third map correlates each one of a plurality of acceptable charging energy values of the energy storage device to a combination of one of a plurality of charging powers of the energy storage device and one of the plurality of SOC values of the energy storage device.

7. The computer-implemented method of claim 6, wherein the third map is established by:
charging the energy storage device at a constant charging power from an initial operating point to an end operating point, and measuring charging current of the energy storage device at different time steps during the charging;
calculating an SOC value at each of a plurality of instantaneous operating points between the initial operating point and the end operating point, by integrating the charging currents at the different time steps; and
calculating one of the plurality of acceptable charging energy values at each instantaneous operating point as a product of the constant charging power and the time difference between the instantaneous operating point and the end operating point.

8. The computer-implemented method of claim 7, wherein the SOC value at each instantaneous operating point for the constant charging power is calculated by:
$${SOC}_{OP} = {SOC}_{H} - \frac{{\int }_{{t}_{OP}}^{{t}_{H}} {I}_{P} ( t ) d t}{{Q}_{TOTAL}}$$
wherein SOC_{OP} denotes the SOC value at the instantaneous operating point, SOC_{H} denotes the SOC value at the end operating point, I_{P}(t) denotes the charging current measured at time t during the charging of the energy storage device, t_{OP} denotes the time at the instantaneous operating point, t_{H} denotes the time at the end operating point, and Q_{TOTAL} denotes the total charge of the energy storage device.

9. The computer-implemented method of claim 7, further including retrieving an instantaneous charge energy efficiency value of the energy storage device from a fourth map based on the charging power and the determined instantaneous SOC value of the energy storage device,
wherein the fourth map correlates each of a plurality of charge energy efficiency values of the energy storage device to a combination of one of the plurality of charging powers of the energy storage device and one of the plurality of SOC values of the energy storage device.

10. The computer-implemented method of claim 9, wherein the fourth map is established by calculating one of the plurality of charge energy efficiency values at each instantaneous operating point, by:
$$\begin{matrix}{η}_{C} = \frac{Δ {E}_{ABSOLUTE}}{{E}_{ACCEPTABLE}} \\ = \frac{{\sum }_{{SOC}_{OP}}^{{SOC}_{H}} \frac{1}{2} {C}_{SOC} ( {V}_{{OC}_{SOC + δ}}^{2} - {V}_{{OC}_{SOC - δ}}^{2} )}{{E}_{ACCEPTABLE}}\end{matrix}$$
wherein η_{C} denotes the charge energy efficiency value at the instantaneous operating point, ΔE_{ABSOLUTE} denotes the change in an absolute energy of the energy storage device between the instantaneous operating point and the end operating point, E_{ACCEPTABLE} denotes a corresponding acceptable charging energy value retrieved from the third map based on the constant charging power and the SOC value of the energy storage device at the instantaneous operating point, C_{SOC} denotes a capacitance of the energy storage device measured when an SOC value of the energy storage device is SOC, V_{SOC+δ} denotes an open circuit voltage of the energy storage device measured when an SOC value of the energy storage device is SOC+δ, V_{OC}_{_{SOC−δ}} is an open circuit voltage of the energy storage device measured when an SOC value of the energy storage device is SOC−δ, and δ is an infinitesimal small value.

11. The computer-implemented method of claim 1, further including retrieving an instantaneous round-trip energy efficiency value of the energy storage device from a fifth map based on the discharging power, a charging power, and the determined instantaneous SOC value of the energy storage device,
wherein the fifth map correlates each one of a plurality of round-trip energy efficiency values of the energy storage device to a combination of one of a plurality of discharging powers of the energy storage device, one of a plurality of charging powers of the energy storage device, and one of a plurality of SOC values of the energy storage device.

12. The computer-implemented method of claim 11, wherein the fifth map is established by calculating one of the plurality of round-trip energy efficiency values at each one of a plurality of instantaneous operating points between an initial operating point and an end operating point, for each constant discharging power and each constant charging power, by:
η_{RTrip}=η_{D}×η_{C}
wherein η_{RTrip} denotes the round-trip energy efficiency value, η_{D} denotes an instantaneous discharge energy efficiency value retrieved from a second map based on the constant discharging power and the SOC value of the energy storage device at the instantaneous operating point, and η_{C} denotes an instantaneous charge energy efficiency value retrieved from a fourth map based on the constant charging power and the SOC value of the energy storage device at the instantaneous operating point,
the second map correlates each of a plurality of discharge energy efficiency values of the energy storage device to a combination of one of the plurality of discharging powers of the energy storage device and one of the plurality of SOC values of the energy storage device, and
the fourth map correlates each of a plurality of charge energy efficiency values of the energy storage device to a combination of one of the plurality of charging powers of the energy storage device and one of the plurality of SOC values of the energy storage device.

13. The computer-implemented method of claim 11, wherein the first through fifth maps are stored in a non-volatile memory.

14. The computer-implemented method of claim 11, wherein first through fifth maps are established through physical experiments or computer simulation.

15. A system for characterization of an energy storage device, comprising:
a storage device storing a first map correlating each of a plurality of available discharging energy values of the energy storage device to a combination of one of a plurality of discharging powers of the energy storage device and one of a plurality of state of charge (SOC) values of the energy storage device;
one or more memories storing instructions; and
one or more processors capable of executing the instructions to:
determine an instantaneous SOC value of the energy storage device during operation of the energy storage device; and
retrieve an instantaneous available discharging energy value of the energy storage device from the first map based on a discharging power and the determined instantaneous SOC value of the energy storage device.

16. The system of claim 15, wherein,
the storage device further stores a second map correlating each of a plurality of discharge energy efficiency values of the energy storage device to a combination of one of the plurality of discharging powers of the energy storage device and one of the plurality of SOC values of the energy storage device, and
the one or more processors are capable of executing the instructions to retrieve an instantaneous discharge energy efficiency value of the energy storage device from the second map based on the discharging power and the determined instantaneous SOC value of the energy storage device.

17. The system of claim 16, wherein,
the storage device further stores a third map correlating each one of a plurality of acceptable charging energy values of the energy storage device to a combination of one of a plurality of charging powers of the energy storage device and one of the plurality of SOC values of the energy storage device, and
the one or more processors are capable of executing the instructions to retrieve an instantaneous acceptable charging energy value of the energy storage device from the third map based on a charging power and the determined instantaneous SOC value of the energy storage device.

18. The system of claim 17, wherein,
the storage device further stores a fourth map correlating each of a plurality of charge energy efficiency values of the energy storage device to a combination of one of the plurality of charging powers of the energy storage device and one of the plurality of SOC values of the energy storage device, and
the one or more processors are capable of executing the instructions to retrieve an instantaneous charge energy efficiency value of the energy storage device from the fourth map based on the charging power and the determined instantaneous SOC value of the energy storage device.

19. The system of claim 18, wherein,
the storage device further stores a fifth map correlating each one of a plurality of round-trip energy efficiency values of the energy storage device to a combination of one of the plurality of discharging powers of the energy storage device, one of the plurality of charging powers of the energy storage device, and one of the plurality of SOC values of the energy storage device, and
the one or more processors are capable of executing the instructions to retrieve an instantaneous round-trip energy efficiency value of the energy storage device from the fifth map based on the discharging power, the charging power, the determined instantaneous SOC value of the energy storage device.

20. A computer-implemented method for characterization of an energy storage device, the method comprising:
determining an instantaneous state of charge (SOC) value of the energy storage device during operation of the energy storage device; and
retrieving an instantaneous acceptable charging energy value of the energy storage device from a map based on a charging power and the determined instantaneous SOC value of the energy storage device,
wherein the map correlates each of a plurality of acceptable charging energy values of the energy storage device to a combination of one of a plurality of charging powers of the energy storage device and one of a plurality of SOC values of the energy storage device.
